(19) United States
(12) Patent Application Publication
(10) Pub. No.: US 2019/0165002 A1
(43) Pub. Date: May 30, 2019

(54) OXIDE THIN FILM TRANSISTOR, FABRICATING METHOD THEREFOR, ARRAY SUBSTRATE, AND DISPLAY DEVICE

(71) Applicants: BOE TECHNOLOGY GROUP CO., LTD., Beijing (CN); Hefei Xinsheng Optoelectronics Technology Co., Ltd, Anhui (CN)

(72) Inventor: Leilei CHENG, Beijing (CN)

(21) Appl. No.: 15/986,040

(22) Filed: May 22, 2018

(30) Foreign Application Priority Data
Nov. 28, 2017 (CN) 201711215165.0

(51) Int. Cl. H01L 27/12; H01L 29/66; H01L 29/423; H01L 29/786; G02F 1/1335; G02F 1/1368

(52) U.S. Cl. CPC H01L 27/1225; H01L 27/1259; H01L 29/66742; G02F 2001/13685; H01L 29/7869; G02F 1/133512; G02F 1/1368; H01L 29/42384

(57) ABSTRACT

The present disclosure provides an oxide TFT, a fabricating method therefor, an array substrate and a display device. The method for fabricating an oxide TFT includes: providing a substrate; successively forming a light shielding layer, a first insulating layer and a semiconductor layer on the substrate; successively forming a second insulating layer, a gate, and a third insulating layer on the semiconductor layer, wherein an orthographic projection of the second insulating layer on the substrate covers an orthographic projection of the semiconductor on the substrate; removing the second insulating layer and the third layer covering regions to be conducted of the semiconductor layer; processing the regions to be conducted by a conducting process to form conducted regions; and forming a first electrode and a second electrode on the conducted regions.

### CROSS REFERENCE

The present application is based upon and claims priority to Chinese Patent Application No. 201711215165.0, filed on Nov. 28, 2017 and titled “Oxide Thin Film Transistor, Fabricating Method Therefor, Array Substrate, and Display Device”, and the entire contents thereof are incorporated herein by reference.

### TECHNICAL FIELD

The present disclosure relates to the field of display technology, in particular, to an oxide thin film transistor, a fabricating method therefor, an array substrate, and a display device.

### BACKGROUND

The oxide thin film transistor (Oxide TFT) is a TFT structure in which a gate is above a channel region. Since the gate is generally used for light protection for the channel region, the TFT of the top gate structure generally has electrical properties better than TFT of the gate of the bottom gate structure.

### SUMMARY

In one aspect, there is provided a method for fabricating an oxide TFT, comprising:

providing a substrate;

successively forming a light shielding layer, a first insulating layer and a semiconductor layer on the substrate;

successively forming a second insulating layer, a gate, and a third insulating layer on the semiconductor layer, wherein an orthographic projection of the second insulating layer on the substrate covers an orthographic projection of the semiconductor layer on the substrate;

removing the second and third insulating layers covering regions to be conducted of the semiconductor layer;

processing the regions to be conducted using a conducting process and forming conducted regions; and

forming a first electrode and a second electrode on the conducted regions.

Further, prior to forming the third insulating layer, the second insulating layer formed by a patterning process is made to cover the semiconductor layer to cover the region to be conducted.

Further, the second insulating layer covering on the region to be conducted has a thickness greater than a preset thickness threshold.

Further, prior to forming the first electrode and the second electrode on the conducted region, the method further comprises: removing the first insulating layer and the third insulating layer covering a preset region of the light shielding layer to form a connecting hole which is configured to connect the light shielding layer and the first electrode after the first electrode and the second electrode are formed.

Further, the step of removing the first insulating layer and the third insulating layer covering a preset region of the light shielding layer to form a connecting hole comprises: removing the third insulating layer covering the preset region of the light shielding layer; and removing the first insulating layer covering the preset region of the light shielding layer while removing the third and second insulating layers covering the region to be conducted.

Further, the step of removing the first insulating layer and the third insulating layer covering a preset region of the light shielding layer to form a connecting hole comprises: removing the third insulating layer covering the preset region of the light shielding layer while removing the third insulating layer covering the region to be conducted; and removing the first insulating layer covering the preset region of the light shielding layer while removing the second insulating layer covering the region to be conducted.

Further, the step of processing the region to be conducted using a conducting process comprises: performing the conducting process on the region to be conducted using plasma to reduce oxygen content of semiconductor at the region to be conducted.

Further, after forming the first electrode and the second electrode on the conducted region, the method further comprises: forming a fourth insulating layer as a passivation layer on the first electrode, the second electrode and the third insulating layer.

In another aspect, there is further provided an oxide thin film transistor comprising a substrate, a light shielding layer formed on a side of the substrate, a first insulating layer formed on a side of the light shielding layer facing away from the substrate to cover the light shielding layer, a semiconductor layer formed on a side of the first insulating layer facing away from the substrate and comprising conducted regions at opposing ends, a second insulating layer formed on a side of the semiconductor layer facing away from the substrate to cover part of the semiconductor layer between the conducted regions, a gate formed on a side of the second insulating layer facing away from the substrate, a third insulating layer formed on a side of the first insulating layer facing away from the substrate to cover the gate, and a first and a second electrodes formed on a side of the third insulating layer facing away from the substrate and connected with the conducted regions of the semiconductor layer through via holes, respectively. The above oxide TFT may be the one fabricated by the aforesaid method for fabricating oxide TFT.

In still another aspect, there is further provided an array substrate comprising the above oxide TFT.

In still another aspect, there is further provided a display device comprising the above array substrate.

### BRIEF DESCRIPTION OF THE DRAWINGS

FIG. 1 is a flowchart of a method for fabricating an oxide TFT according to an embodiment of the present disclosure.

FIG. 2 is a flowchart of another method for fabricating an oxide TFT according to an embodiment of the present disclosure.

FIG. 3 is a first schematic view illustrating a process flowchart of fabricating an oxide TFT according to an embodiment of the present disclosure.

FIG. 4 is a second schematic view illustrating a process flowchart of fabricating an oxide TFT according to an embodiment of the present disclosure.

FIG. 5 is a third schematic view illustrating a process flowchart of fabricating an oxide TFT according to an embodiment of the present disclosure.

FIG. 6 is a fourth schematic view illustrating a process flowchart of fabricating an oxide TFT according to an embodiment of the present disclosure.

FIG. 7 is a fifth schematic view illustrating a process flowchart of fabricating an oxide TFT according to an embodiment of the present disclosure.

FIG. 8 is a sixth schematic view illustrating a process flowchart of fabricating an oxide TFT according to an embodiment of the present disclosure.

FIG. 9 is a seventh schematic view illustrating a process flowchart of fabricating an oxide TFT according to an embodiment of the present disclosure.

FIG. 10 is an eighth schematic view illustrating a process flowchart of fabricating an oxide TFT according to an embodiment of the present disclosure.

FIG. 11 is a schematic view illustrating another etched state of the insulating layers according to an embodiment of the present disclosure.

FIG. 12 is a schematic view illustrating a sectional structure of an array substrate according to an embodiment of the present disclosure.

### DETAILED DESCRIPTION

Now further detailed description will be made to the disclosure in conjunction with the accompanying drawings and specific embodiments in order to make the objectives, features, and advantages of the present disclosure more comprehensible.

In the description of the present disclosure, unless otherwise specified, “a plurality of” means two or more. The terms such as “upper”, “lower”, “left”, “right”, “inner”, “outer” and the like indicate the orientations or positional relationships based on the orientations or positional relationships shown in the drawings, and are merely for the convenience of describing the present disclosure and the simplified description, but do not indicate or imply that the referred machine or element must have or be operated in a specific orientation or a specific orientation, which are therefore not to be construed as limiting the present disclosure.

In the description of the present disclosure, it should be noted that the terms “mount”, “inter-connect”, and “connect” should be understood in a broad sense unless specifically defined or limited otherwise, and may be, for example, a fixed connection or a detachable connection or an integrated connection. Alternatively, the connection may be a physical connection or an electrical connection. Also, it can be a direct connection or indirect connection through an intermediary. For a person of ordinary skill in the art, the specific meanings of the above terms in the present disclosure can be understood in specific situations. In the embodiments of the present disclosure, to distinguish the two electrodes other than the gate of the transistor, the source and the drain thereof are referred to as the first electrode and the second electrode, respectively.

The specific implementation of the present disclosure will be further described in detail below with reference to the accompanying drawings and embodiments. The following embodiments are intended to illustrate the present disclosure but are not intended to limit the scope of the disclosure.

In the prior art, in order to form an oxide thin film transistor (Oxide TFT) of the top gate structure, when the second insulating layer between the semiconductor layer and the gate is formed through a patterning process, the second insulating layer covering regions to be conducted of the semiconductor layer, i.e., regions of the semiconductor layer to be electrically connected with for example the source and the drain, is usually completely etched to expose the region to be conducted. The regions to be conducted are then processed using a conducting process, for example, by a plasma process using for example H₂, He or O₂. After performing the conducting process on the region to be conducted, the third insulating layer is formed.

However, on one hand, while forming the third insulating layer, the third insulating layer will be formed on the surface of the conducted region and is in contact with the conducted region. In addition, processes such as high temperature and plasma impacting are performed during the forming of the third insulating layer. For example, while forming the third insulating layer using a plasma enhanced chemical vapor deposition (PECVD) process, the deposition temperature may be about 300° C., and large amounts of plasma may exist in the chamber of the PECVD apparatus. During the processes, oxide ions in the semiconductor layer may be taken away such that the conducted semiconductor will undergo further conducting process, which in turn may result in shortening the channel of the TFT and generating a short-channel effect. The short-channel effect means that as the TFT channel is shortened, the threshold voltage Vth significantly shifts negatively, which affects the stability of the TFT.

On the other hand, after etching the third insulating layer covering the conducted regions, the third insulating layer and the second insulating layer may have a relative large thickness. Accordingly, the depth of the connecting hole is relative large, which may cause accumulation of the impurities generated during the process of curing the photoresist or etching of the organic polymer or the like. Also, as the connecting hole is deep, the impurities generated during the process of curing the photoresist or etching of the organic polymer may be difficult to be cleaned completely by peeling liquid, and thus may be left as residues in the hole. These residues in the hole cover the surface of the conducted regions, will increase the contact resistance between the first electrode, the second electrode and the conducted regions, and in turn will affect the display quality of the display panel.

Embodiments of the present disclosure provide an oxide TFT, a fabricating method therefor, an array substrate and a display, which may solve the problem of short-channel effect during the forming process of the TFT with top gate structure.

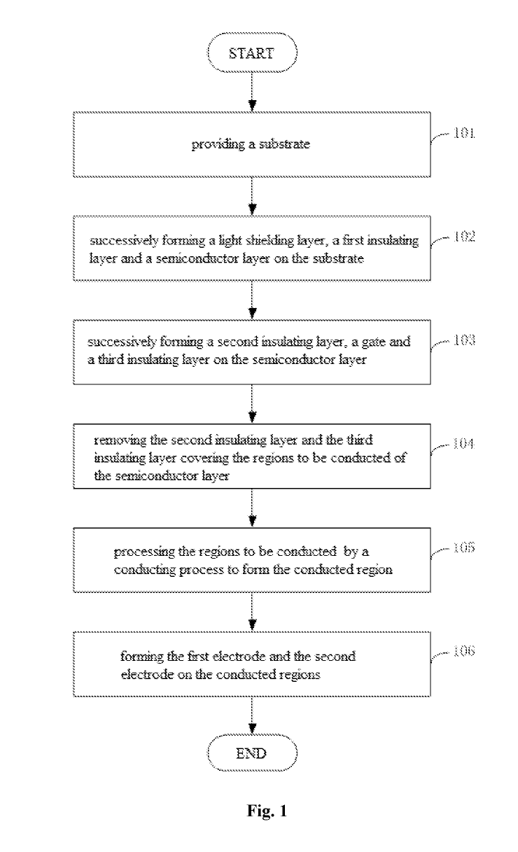

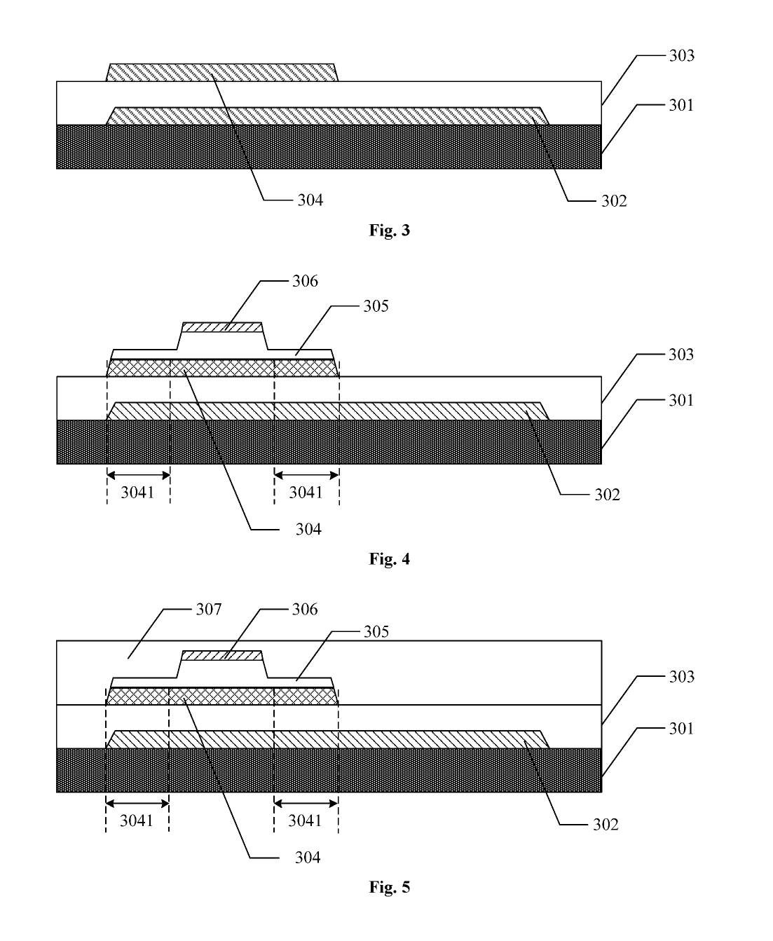

Referring to FIG. 1, which illustrates a flowchart of a method for fabricating an oxide TFT according to an embodiment of the present disclosure. Referring to FIGS. 3-10, which illustrate schematic views of process flowchart of fabricating an oxide TFT according to an embodiment of the present disclosure.

In step 101, a substrate is provided.

In particular, the substrate 301 may be a rigid substrate or a flexible substrate.

In step 102, a light shielding layer, a first insulating layer and a semiconductor layer are formed successively on the substrate.

As illustrated in FIG. 3, the light shielding layer 302 may be formed on the substrate 301 with an opaque material. For example, a black matrix (BM) layer may be formed as the light shielding layer 302, or a metal layer may be used as the light shielding layer 302. Wherein, the BM layer is a black photoresist layer made by a patterning process.

After the light shielding layer 302 is formed, a first insulating layer 303, for example, an insulating thin film, is formed on the light shielding layer 302. A metal oxide semiconductor thin film is formed on the first insulating layer 303 to form a semiconductor layer 304 through a patterning process. In the present embodiment, the patterning process comprises the steps such as photolithography, etching and peeling.

In step 103, a second insulating layer, a gate and a third insulating layer are formed successively on the semiconductor layer.

In the embodiment, an orthographic projection of the second insulating layer 305 on the substrate 301 covers an orthographic projection of the semiconductor layer 304 on the substrate 301.

In particular, as illustrated in FIG. 4, the second insulating layer 305 and the gate 306 may be formed firstly, and the gate 306 and the second insulating layer 305 may be patterned by a patterning process. In the present embodiment, while patterning the patterned second insulating layer 305, the second insulating layer 305 covering the regions to be conducted 3041 may remain such that the second insulating layer 305 covering the regions to be conducted 3041 may protect the regions to be conducted 3041, and may prevent conducting the regions to be conducted 3041 while forming the third insulating layer 307.

As illustrated in FIG. 5, after successively forming the patterned gate 306 and the second insulating layer 305 on the semiconductor layer 304, the third insulating layer 307 is formed. While forming the third insulating layer 307, the regions to be conducted 3041 in the semiconductor layer 304 under the cover of the second insulating layer 305 may be prevented from being affected by the high temperature, plasma impacting or the like during the fabricating process, thereby preventing the oxygen ion in the semiconductor material from being taken away, whereby the property of the semiconductor layer 304 in said regions will not change.

In step 104, the second insulating layer and the third insulating layer covering the regions to be conducted in the semiconductor layer are removed.

After forming the third insulating layer 307 on the gate 306, the impact on the regions to be conducted 3041 during the fabricating process of the third insulating layer 307 is eliminated. By performing conducting process on the regions to be conducted 3014 with maintained semiconducting property, it is possible to precisely control the degree of the conducting of the regions to be conducted 3014, thereby preventing over-conducting. In order to perform conducting process on the regions to be conducted 3014, the second insulating layer 305 and the third insulating layer 307 covering the regions to be conducted 3014 in the semiconductor layer 304 have to be removed to expose the regions to be conducted 3014.

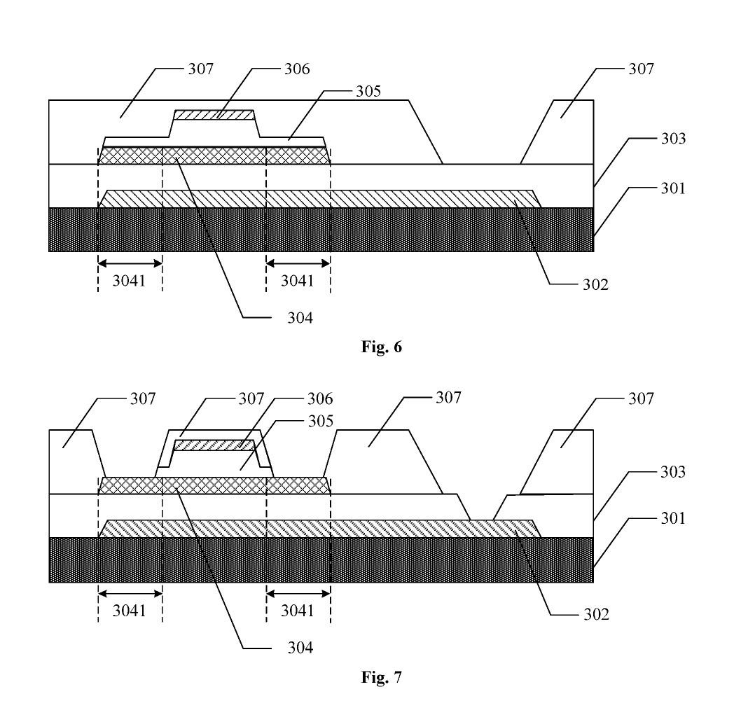

In particular, as illustrated in FIGS. 6 and 7, while removing the second insulating layer 305 and the third insulating layer 307 covering the regions to be conducted 3014 in the semiconductor layer 304, the connecting hole may be formed stepwise since the second insulating layer 305 and the third insulating layer 307 may have a relatively large thickness. For example, a portion of the insulating thin films covering the regions to be conducted 3014 may be removed by etching at a first speed, and the remaining portion of the insulating thin films may be removed by etching at a second speed, which is less than the first speed, to expose the regions to be conducted 3014. Accordingly, the connecting hole may have a relative gentle slop angle.

In step 105, the regions to be conducted are processed by a conducting process to form the conducted regions.

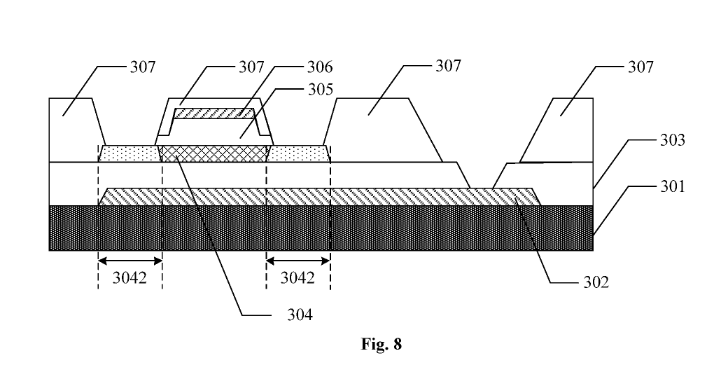

In particular, as illustrated in FIG. 8, after removing the second insulating layer 305 and the third insulating layer 307 covering the regions to be conducted 3014 in the semiconductor layer 304, the regions to be conducted 3014 may be processed using a conducting process to form the conducted regions 3042. In the present embodiment, the type of the conducting process is not limited, and a corresponding conducting process may be selected according to the specific semiconductor material.

In an actual application, when the plasma used during the conducting process is applied on the surface of the regions to be conducted 3014, the impurities such as the cured photoresist, the organic polymer and the like remaining on the regions to be conducted 3014 when etching the third insulating layer 307 and the second insulating layer may be removed. Accordingly, the surface of the regions to be conducted 3014 may be cleaned effectively, thereby preventing these impurities from increasing the contact resistance between the conducted regions 3042 and the respective first electrode 308 and second electrode 309.

In step 106, the first electrode and the second electrode are formed on the conducted regions.

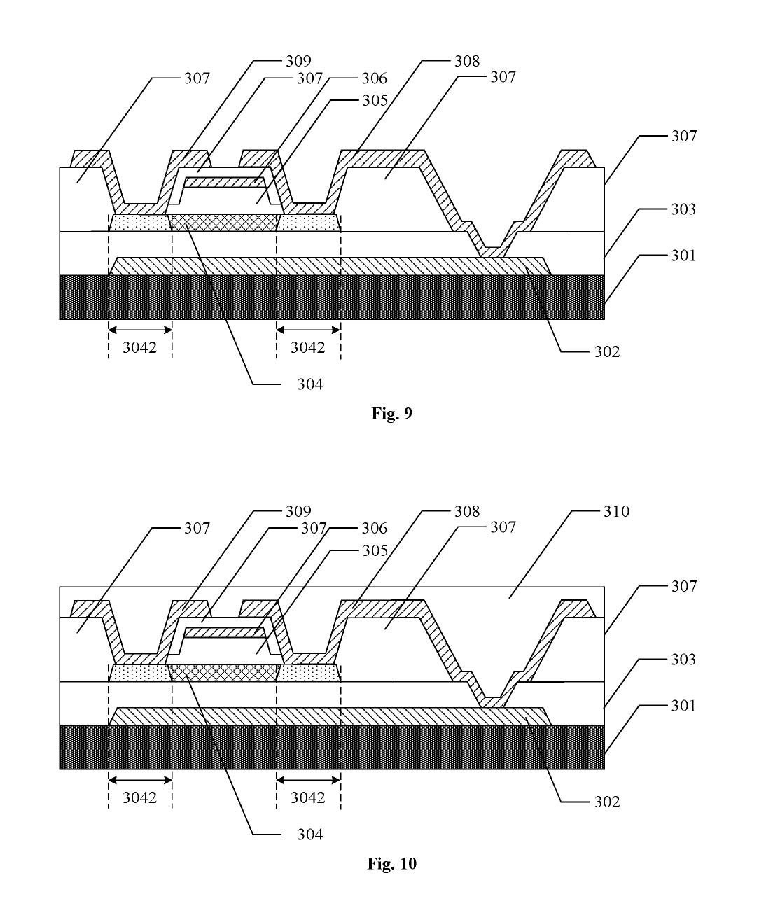

In particular, as illustrated in FIG. 9, after forming the conducted regions 3042 by performing the conducting process on the regions to be conducted 3014, the first electrode 308 and the second electrode 309 of the TFT may be formed on the conducted regions 3042. The first electrode 308 and the second electrode 309 cover and are connected with the conducted regions 3042.

As mentioned above, in the embodiments of the present disclosure, by successively forming the second insulating layer 305, the gate 306 and the third insulating layer 307 on the semiconductor layer 304, then removing the second insulating layer 305 and the third insulating layer 307 covering the regions to be conducted 3014 in the semiconductor layer 304 by a patterning process on the third insulating layer 307, and then processing the regions to be conducted 3014 using the conducting process, the conducted regions 3042 may be formed. Accordingly, the regions to be conducted 3014, under the cover of the second insulating layer 305, may be prevented from being over-conducted while forming the third insulating layer 307. and therefore it is possible to prevent the generation of the short channel effect and effectively improve the electrical performance of the oxide TFT of the top gate structure. Also, the impurities accumulated on the surface of the regions to be conducted 3014 may be cleaned by the conducting process, thereby reducing the contact resistance between the conducted regions 3042 and the respective first electrode 308 and second electrode 309 and improving the display quality of the display panel.

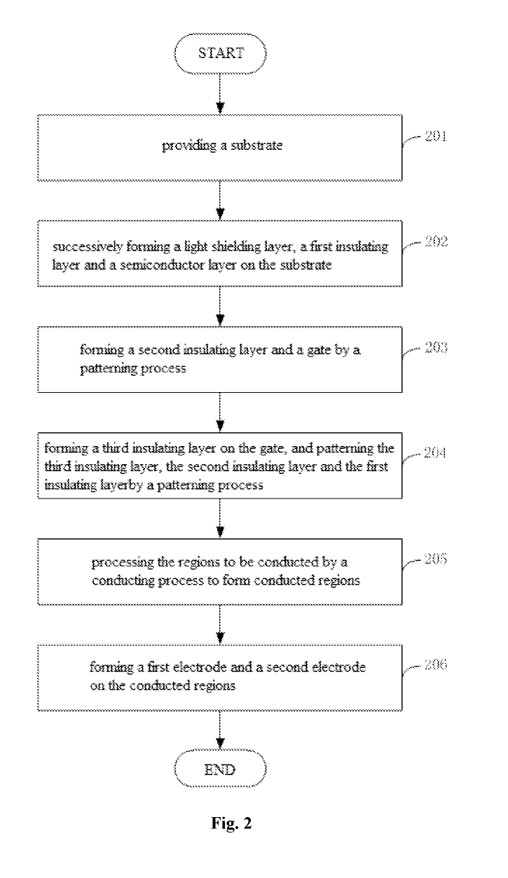

Referring to FIG. 2, a flowchart of another method for fabricating the oxide TFT according to an embodiment of the present disclosure is illustrated.

In step 201, a substrate is provided.

In particular, the substrate 301 may be a flexible substrate or a rigid substrate and may be formed of a material having excellent mechanical strength or dimensional stability for forming the element. For example, the material of the substrate 301 may comprise glass, metal, ceramic, plastic, or the like. In the present embodiment, the plastic material used for preparing the substrate 301 may comprise polycarbonate resin, acrylic resin, vinyl chloride resin, polyethylene terephthalate resin, polyimide resin, polyester resin, epoxy resin, silicone resin, fluorine resin, etc.

In step 202, the light shielding layer, the first insulating layer and the semiconductor layer are formed successively on the substrate.

In particular, the first insulating layer 303 may be formed by an inorganic insulating film. The material for preparing the inorganic insulating film may comprise: silicon oxide (SiOx), silicon nitride (SiNx), hafnium oxide (HfOx), silicon nitride oxidation (SiON), aluminum oxide (AlOx), organic material, or a combination thereof. In a practical application, the second insulating layer 305, the third insulating layer 307, and the fourth insulating layer 310 may also be formed by the inorganic insulating film. Different materials can be selected to prepare the insulating films according to the role played by different insulating layers.

The semiconductor layer 304 may be formed of an oxide semiconductor material, which may comprise an oxide semiconductor of one or more of indium (In), gallium (Ga), zinc (Zn), oxygen (O), tin (Sn), or the like. Optionally, the oxide semiconductor material may comprise one of indium gallium zinc oxide (IGZO), indium zinc oxide (IZO), indium tin oxide (InSnO), indium tin oxide (InGaSnO). Optionally, the thickness of the semiconductor layer 304 may be between 30-100 nm.

In step 203, the second insulating layer and the gate are formed by a patterning process.

As illustrated in FIG. 4, after successively forming the light shielding layer 302, the first insulating layer 303 and the semiconductor layer 304, the gate 306 may be formed firstly by a patterning process, and then the second insulating layer 305 may be formed by a patterning process.

In particular, while forming the second insulating layer 305 using the patterning process, the second insulating layer 305 not covering the semiconductor layer 304 and the second insulating layer 305 covering the regions to be conducted 3041 may be etched to different degrees. For example, the second insulating layer 305 not covering the semiconductor layer 304 may be etched completely, while the second insulating layer 305 covering the regions to be conducted 3041 are not etched completely such that the second insulating layer 305 covering the regions to be conducted 3041 has a thickness greater than a preset thickness threshold, whereby the second insulating layer 305 covering the regions to be conducted 3041 may effectively protect the regions to be conducted 3041 and the conducting will not occur to the regions to be conducted 3041 while forming the third insulating layer 307. Further, that a portion of the second insulating layer 305 covering the regions to be conducted 3041 is etched is also beneficial to reduce the thickness of the etched object when etching the two insulating layers after the third insulating layer 307 is formed, thereby saving the amount of the etching solution and reducing the time required for the process.

In a practical application, the material for preparing the gate 306, the first electrode 308, and the second electrode 309 may comprise a single layer or multi-layer-composed stacked layers of one or more of Mo, MoNb alloy, Al, AlNd alloy, Ti and Cu.

In step 204, the third insulating layer is formed on the gate, and the third insulating layer, the second insulating layer and the first insulating layer are patterned using a patterning process.

When patterning the third insulating layer 307, the second insulating layer 305 and the first insulating layer 303, the second insulating layer 305 and the third insulating layer 307 covering the regions to be conducted 3041 in the semiconductor layer 304 may be removed using the patterning process to expose the regions to be conducted 3041. Also, the first insulating layer 303 and the third insulating layer 307 covering a preset region of the light shielding layer 302 may be removed by the patterning process to form the connecting hole which is configured to connect the light shielding layer to the first electrode 308 after the first electrode 308 and the second electrode 309 are formed. Accordingly, the first electrode 308 may take away the charge accumulated on the light shielding layer 302 in time to improve the uniformity of the threshold voltage.

In particular, the third insulating layer 307 covering the preset region of the light shielding layer 302 may be removed firstly. Afterwards, the first insulating layer 303 covering the preset region of the light shielding layer 302 may be removed while removing the third insulating layer 307 and the second insulating layer 305 covering the regions to be conducted 3041, to form the connecting hole. Alternatively, the third insulating layer 307 covering the preset region of the light shielding layer 302 may be removed while removing the third insulating layer 307 covering the regions to be conducted 3041; and removing the first insulating layer 305 covering the preset region of the light shielding layer 302 may be removed while removing the second insulating layer 305 covering the regions to be conducted 3041.

In a practical application, in the process of patterning the third insulating layer 307, the second insulating layer 305 and the first insulating layer 303, the third insulating layer 307 at the connecting hole may be etched firstly as illustrated in FIG. 6, and then the third insulating layer 307 and the second insulating layer 305 covering the regions to be conducted 3041 and the first insulating layer 303 at the connecting hole may be etched as illustrated in FIG. 7. Referring to FIG. 11, a schematic view illustrating another etched state of the insulating layers according to an embodiment of the present disclosure is illustrated. As illustrated in FIG. 11, firstly, the third insulating layer 307 at the connecting hole as well as the third insulating layer 307 covering the regions to be conducted 3041 may be etched at the same time, and then the second insulating layer 305 covering the regions to be conducted 3041 as well as the first insulating layer 303 at the connecting hole may be etched. In particular, the order and speed of the etching of insulating layers at respective positions may be determined according to the thickness of each insulating layers, which is not limited to the above two schemes.

In step 205, the regions to be conducted are processed using a conducting process to form the conducted regions.

In particular, as illustrated in FIG. 8, a conducting process may be performed on the regions to be conducted 3041 using plasma to reduce the content of oxygen at the regions to be conducted 3041. For example, the conducting process may be performed on the regions to be conducted 3041 using He plasma, NH₃ plasma, H₂ plasma or the like.

In step 206, the first electrode and the second electrode are formed on the conducted regions.

In particular, as illustrated in FIG. 9, after performing conducting process on the regions to be conducted 3041 to form the conducted regions 3042, the first electrode 308 and the second electrode 309 of the TFT may be formed on the conducted regions 3042. The first electrode 308 and the second electrode 309 cover and are connected with the conducted regions 3042. In a practical application, as illustrated in FIG. 10, after forming the first electrode 308 and the second electrode 309 on the conducted regions, a fourth insulating layer 310 may be further formed as a passivation layer to protect the TFT.

As mentioned above, in the embodiments of the present disclosure, by partly etching the second insulating layer 305 covering the regions to be conducted 3041 before forming the third insulating layer 307, the regions to be conducted 3041 may be protected against the conducting, and the etching burden of the two insulating layers after forming the third insulating layer 307 may be reduced, thereby the consumption of the etching solution and the time required for the process may be reduced. Further, that the light shielding layer 302 is connected to the first electrode 308 or the second electrode 309 via the connecting hole, the first electrode 308 or the second electrode 309 may take away the charge accumulated on the light shielding layer 302 in time to improve the uniformity of the threshold voltage.

There is accordingly provided an oxide thin film transistor comprising a substrate, a light shielding layer formed on a side of the substrate, a first insulating layer formed on a side of the light shielding layer facing away from the substrate to cover the light shielding layer, a semiconductor layer formed on a side of the first insulating layer facing away from the substrate and comprising conducted regions at opposing ends, a second insulating layer formed on a side of the semiconductor layer facing away from the substrate to cover part of the semiconductor layer between the conducted regions, a gate formed on a side of the second insulating layer facing away from the substrate, a third insulating layer formed on a side of the first insulating layer facing away from the substrate to cover the gate, and a first and a second electrodes formed on a side of the third insulating layer facing away from the substrate and connected with the conducted regions of the semiconductor layer through via holes, respectively. The above oxide TFT may be the one fabricated by the aforesaid method for fabricating oxide TFT.

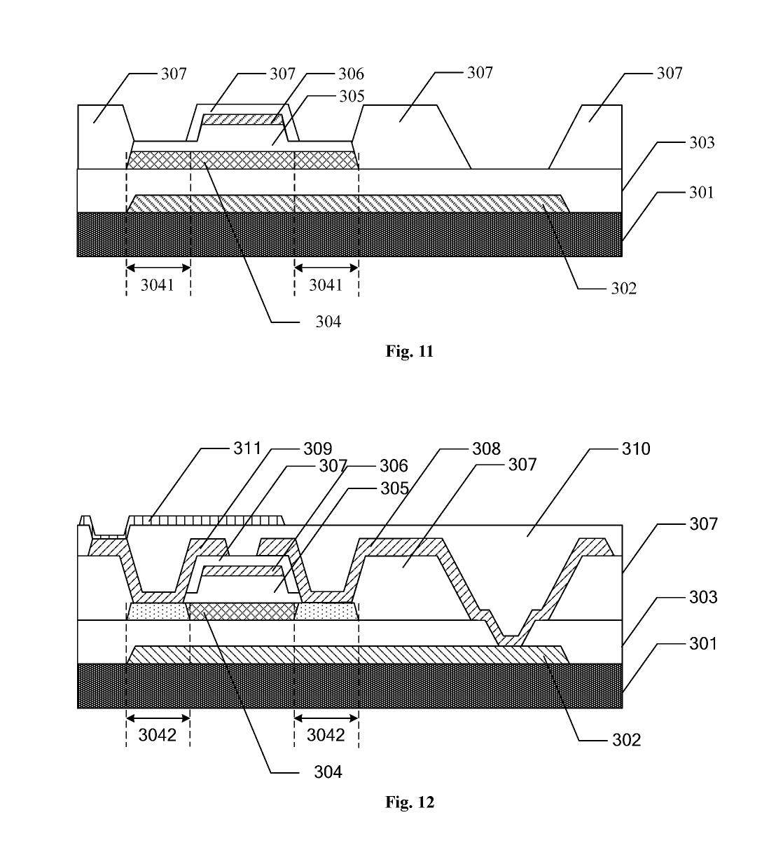

On the basis of the above embodiments, referring to FIG. 12, an embodiment of the present disclosure further provides an array substrate comprising the above oxide TFT. As those skilled in the art may appreciate, the array substrate may further comprise a pixel electrode 311 on the fourth insulating layer 310. In the present embodiment, the pixel electrode 311 may be formed of transparent conductive material such as indium tin oxide (ITO), indium zinc oxide (IZO) or the like, which is not limited therein.

Further, an embodiment of the present disclosure further provides a display device comprising the above array substrate. In particular, the display device may be any product or component having a display function such as a liquid crystal display panel, an OLED display panel, an electronic paper, an organic light emitting display panel, a mobile phone, a tablet computer, a television, a display, a notebook computer, a digital photo frame, a navigator, and the like.

The present disclosure provides an oxide TFT, a fabricating method therefor, an array substrate and a display device. In the method for fabricating the oxide TFT according to the present disclosure, by removing the second insulating layer and the third insulating layer covering the regions to be conducted in the semiconductor layer after successively forming the second insulating layer, the gate and the third insulating layer, and then processing the regions to be conducted using a conducting process, the conducted regions are formed. Accordingly, the regions to be conducted, under the cover of the second insulating layer, may be prevented from being over-conducted while forming the third insulating layer. Therefore, it is possible to prevent the generation of the short channel effect and effectively improve the electrical performance of the oxide TFT of the top gate structure.

Respective embodiments in this specification are described in a progressive manner, and each embodiment focuses on the differences from other embodiments, and the same or similar parts among the embodiments can be referred to each other.

Hereinabove, the oxide TFT, the fabricating method therefor, the array substrate, and the display device provided by the present disclosure are explained in detail. Specific examples are used in the present disclosure to explain the principle and implementation manners of the present disclosure, and the above embodiments are only described to help those skilled in the art understand the method and key concept of the present disclosure. Meanwhile, those skilled in the art, based on the concept of the present disclosure, will make changes for specific embodiments and applications. In sum, the contents of this specification should not be construed as limiting the present disclosure.

What is claimed is:

1. A method for fabricating an oxide thin film transistor, comprising:
providing a substrate;
successively forming a light shielding layer, a first insulating layer and a semiconductor layer on the substrate;
successively forming a second insulating layer, a gate, and a third insulating layer on the semiconductor layer, wherein an orthographic projection of the second insulating layer on the substrate covers an orthographic projection of the semiconductor on the substrate;
removing the second insulating layer and the third layer covering regions to be conducted of the semiconductor layer;
processing the regions to be conducted using a conducting process to form conducted regions; and
forming a first electrode and a second electrode on the conducted regions.

2. The method according to claim 1, wherein the step of successively forming the second insulating layer, the gate, and the third insulating layer on the semiconductor layer comprises: forming the second insulating layer and the gate firstly, and patterning the gate and the second insulating layer successively by patterning processes, and then forming the third insulating layer.

3. The method according to claim 1, wherein the second insulating layer is formed by a patterning process, and the second insulating layer not covering the semiconductor layer and the second insulating layer covering the regions to be conducted are etched.

4. The method according to claim 1, wherein the second insulating layer covering the regions to be conducted has a thickness greater than a preset thickness threshold.

5. The method according to claim 1, wherein prior to forming the first electrode and the second electrode on the conducted region, the method further comprises:
removing the first insulating layer and the third insulating layer covering a preset region of the light shielding layer to form a connecting hole;
wherein the connecting hole is configured to connect the light shielding layer and the first electrode after the first electrode and the second electrode are formed.

6. The method according to claim 5, wherein the step of removing the first insulating layer and the third insulating layer covering a preset region of the light shielding layer to form a connecting hole comprises:
removing the third insulating layer covering the preset region of the light shielding layer; and
removing the first insulating layer covering the preset region of the light shielding layer while removing the third insulating layer and the second insulating layer covering the regions to be conducted.

7. The method according to claim 5, wherein the step of removing the first insulating layer and the third insulating layer covering a preset region of the light shielding layer to form a connecting hole comprises:
removing the third insulating layer covering the preset region of the light shielding layer while removing the third insulating layer covering the regions to be conducted; and
removing the first insulating layer covering the preset region of the light shielding layer while removing the second insulating layer covering the regions to be conducted.

8. The method according to claim 1, wherein the step of removing the third insulating layer and the second insulating layer covering the regions to be conducted of the semiconductor layer comprises:
removing a portion of insulating thin films covering the regions to be conducted by etching at a first speed; and
removing a remaining portion of the insulating thin films by etching at a second speed to expose the regions to be conducted such that the connecting hole has a gentle slope angle,
wherein the first speed is larger than the second speed.

9. The method according to claim 1, wherein the step of processing the regions to be conducted by a conducting process comprises:
performing the conducting process on the regions to be conducted using plasma to reduce oxygen content of semiconductor at the regions to be conducted.

10. The method according to claim 1, wherein after forming the first electrode and the second electrode on the conducted region, the method further comprises:
forming a fourth insulating layer as a passivation layer on the first electrode, the second electrode and the third insulating layer.

11. The method according to claim 1, wherein the step of forming the semiconductor layer on the first insulating layer comprises forming a metal oxide semiconductor thin film on the first insulating layer, and forming the semiconductor layer by a patterning process.

12. The method according to claim 1, wherein the substrate is a flexible substrate.

13. The method according to claim 1, wherein the substrate is a rigid substrate.

14. The method according to claim 1, wherein the first insulating layer, the second insulating layer and the third insulating layer are formed by inorganic insulating thin films.

15. The method according to claim 1, wherein the semiconductor layer has a thickness between 30 nm to 100 nm.

16. The method according to claim 1, wherein the step of forming the light shielding layer on the substrate comprises forming the light shielding layer on the substrate using an opaque material.

17. An oxide thin film transistor comprising:
a substrate,
a light shielding layer formed on a side of the substrate,
a first insulating layer formed on a side of the light shielding layer facing away from the substrate to cover the light shielding layer,
a semiconductor layer formed on a side of the first insulating layer facing away from the substrate and comprising conducted regions at opposing ends,
a second insulating layer formed on a side of the semiconductor layer facing away from the substrate to cover part of the semiconductor layer between the conducted regions,
a gate formed on a side of the second insulating layer facing away from the substrate,
a third insulating layer formed on a side of the first insulating layer facing away from the substrate to cover the gate, and
a first and a second electrodes formed on a side of the third insulating layer facing away from the substrate and connected with the conducted regions of the semiconductor layer through via holes, respectively.

18. The oxide thin film transistor according to claim 17, wherein the oxide thin film transistor is fabricated by a method for fabricating an oxide thin film transistor, the method comprises:
providing a substrate;
successively forming a light shielding layer, a first insulating layer and a semiconductor layer on the substrate;
successively forming a second insulating layer, a gate, and a third insulating layer on the semiconductor layer, wherein an orthographic projection of the second insulating layer on the substrate covers an orthographic projection of the semiconductor on the substrate;
removing the second insulating layer and the third layer covering regions to be conducted of the semiconductor layer;
processing the regions to be conducted using a conducting process to form conducted regions; and
forming a first electrode and a second electrode on the conducted regions.

19. An array substrate comprising the oxide thin film transistor according to claim 17.

20. A display device comprising the array substrate according to claim 19.
